(19) United States
(12) Patent Application Publication
(10) Pub. No.: US 2014/0103324 A1
(43) Pub. Date: Apr. 17, 2014

(54) ORGANIC ELECTROLUMINESCENT ELEMENT

(71) Applicant: PANASONIC CORPORATION, Osaka (JP)

(72) Inventors: Masahiro Nakamura, Eindhoven (NL); Masahito Yamana, Hyogo (JP); Mitsuo Yaguchi, Osaka (JP); Takeyuki Yamaki, Nara (JP)

(73) Assignee: PANASONIC CORPORATION, Osaka (JP)

(21) Appl. No.: 14/125,126

(22) PCT Filed: Jul. 26, 2012
(86) PCT No.: PCT/JP2012/069032

§ 371 Date: Dec. 10, 2013

(30) Foreign Application Priority Data
Jul. 27, 2011 (JP) 2011-164187

(51) Int. Cl. H01L 51/52

(52) U.S. Cl. CPC H01L 51/5209; H01L 51/5221; H01L 51/5259
USPC 257/40

(57) ABSTRACT

The organic electroluminescence element in accordance with the present invention includes: a functional layer including a light-emitting layer and having a first surface and a second surface in a thickness direction; a first electrode layer positioned on the first surface of the functional layer; a second electrode layer positioned on the second surface of the functional layer; and a hygroscopic member absorbing moisture. The second electrode layer includes a patterned electrode. The patterned electrode includes: an electrode part covering the second surface of the functional layer; and an opening part formed in the electrode part to expose the second surface of the functional layer. The hygroscopic member is positioned on the electrode part to expose the opening part.

### TECHNICAL FIELD

The present invention relates to organic electroluminescence elements.

### BACKGROUND ART

In the past, there has been proposed an organic electroluminescence light-emitting device with a structure illustrated in FIG. 11 (document 1 [JP 2008-181832 A]).

In this organic electroluminescence light-emitting device, a transparent conductive layer 402 is on a surface of a light-transmissive substrate 401, and an organic light-emitting layer 403 is on the transparent conductive layer 402, and a cathode layer 404 is on the organic light-emitting layer 403. Further, this organic electroluminescence light-emitting device includes: a protective enclosing layer 407 covering a laminate 406 constituted by the organic light-emitting layer 403 and the cathode layer 404; and a hygroscopic-agent-containing enclosing layer 408 covering the protective enclosing layer 407. Furthermore, in this organic electroluminescence light-emitting device, a moisture prevention layer 409 is positioned outside the hygroscopic-agent-containing enclosing layer 408, and is bonded to the light-transmissive substrate 401 with an adhesive layer 410. The hygroscopic-agent-containing enclosing layer 408 is formed by coating an external surface of the protective enclosing layer 407 with a hygroscopic-agent-containing base resin produced by mixing a hygroscopic agent with base resin.

Document 1 discloses that a hygroscopic agent is preferably a compound which has a function of absorbing moisture and is in a solid state even when absorbing moisture. Especially, document 1 discloses that a hygroscopic agent is preferably calcium oxide, barium oxide, silica gel, or the like. According to the example 1 disclosed in document 1, the transparent conductive layer 402 is formed by patterning an ITO film formed on the light-transmissive substrate 401 with sputtering. Further, the cathode layer 404 is formed by depositing Al.

In the organic electroluminescence light-emitting device with the structure illustrated in FIG. 11, light produced in the organic light-emitting layer 403 is emitted outside through the light-transmissive substrate 401.

While, for example, there has been proposed a top-emission type organic electroluminescence element with a structure illustrated in FIG. 12 (document 2 [JP 2006-331694 A]).

In this organic electroluminescence element, one electrode (cathode) 101 is on a surface of a substrate 104, and a light-emitting layer 103 is on a surface of the electrode 101 with an electron injection and transport layer 105 being interposed therebetween, and the other electrode (anode) 102 is on the light-emitting layer 103 with a hole injection and transport layer 106 being interposed therebetween. Further, this organic electroluminescence element includes an enclosing member 107 which is on the surface of the substrate 104. In brief, in this organic electroluminescence element, light produced in the light-emitting layer 103 is emitted outside through the electrode 102 provided as a light-transmissive electrode and the enclosing member 107 formed of transparent material.

The electrode 101 which is reflective may be made of Al, Zr, Ti, Y, Sc, Ag, or In, for example. Further, the electrode 102 which is the light-transmissive electrode may be made of indium tin oxide (ITO) or indium zinc oxide (IZO), for example.

Note that, document 2 teaches that a drying agent is provided into a space enclosed by the enclosing member in order to prevent occurrence and growth of a dark spot and is preferably light transmissive. Further, document 2 teaches that such a drying agent may be opaque depending on a size or a location thereof.

### SUMMARY OF INVENTION

The present invention has aimed to propose an organic electroluminescence element with reduced luminance unevenness and improved reliability.

The organic electroluminescence element in accordance with the present invention includes: a functional layer including a light-emitting layer and having a first surface and a second surface in a thickness direction; a first electrode layer positioned on the first surface of the functional layer; a second electrode layer positioned on the second surface of the functional layer; and a hygroscopic member absorbing moisture. The second electrode layer includes a patterned electrode. The patterned electrode includes: an electrode part covering the second surface of the functional layer; and an opening part formed in the electrode part to expose the second surface of the functional layer. The hygroscopic member is positioned on the electrode part to expose the opening part.

### BRIEF DESCRIPTION OF THE DRAWINGS

FIG. 1 is a schematic sectional view illustrating the organic electroluminescence element of one embodiment in accordance with the present invention;

FIG. 2 is a schematic plan view illustrating the primary part of the organic electroluminescence element of the above embodiment;

FIG. 3 is a schematic plan view illustrating the second electrode of the organic electroluminescence element of the above embodiment;

FIG. 4 is a schematic sectional view illustrating the primary part of the organic electroluminescence element of the above embodiment;

FIG. 5 is a schematic plan view illustrating another configuration of the second electrode of the organic electroluminescence element of the above embodiment;

FIG. 6 is a schematic plan view illustrating another configuration of the second electrode of the organic electroluminescence element of the above embodiment;

FIG. 7 is an explanatory diagram illustrating the method of forming the patterned electrode and the hygroscopic member of the organic electroluminescence element of the above embodiment;

FIG. 8 is an explanatory diagram illustrating another method of forming the patterned electrode and the hygroscopic member of the organic electroluminescence element of the above embodiment;

FIG. 9 is a schematic sectional view illustrating the first modification of the organic electroluminescence element of the above embodiment;

FIG. 10 is a schematic sectional view illustrating the second modification of the organic electroluminescence element of the above embodiment;

FIG. 11 is a sectional view illustrating the example of the prior organic electroluminescence light-emitting device; and

FIG. 12 is a schematic sectional view illustrating the example of the prior organic electroluminescence element.

### DESCRIPTION OF EMBODIMENTS

Generally, to enable the organic electroluminescence element to emit light with high luminance, it is necessary to supply a large current. However, in a general organic electroluminescence element, the anode formed of an ITO film has a larger sheet resistance than that of the cathode formed of a metal film, an alloy film, a metal compound film or the like. Therefore, the anode tends to have a larger potential gradient and therefore in-plane unevenness in luminance is likely to increase.

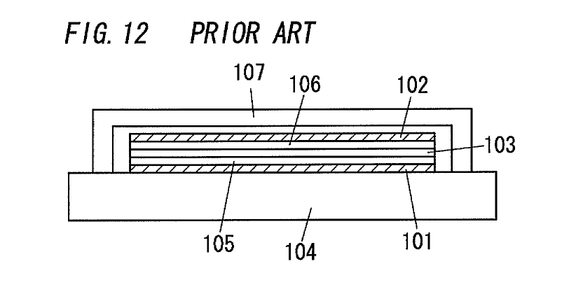

For the same reason, in the organic electroluminescence element with the structure shown in FIG. 12, luminance unevenness is likely to occur due to a high sheet resistance of the electrode 102.

The present inventors considered providing the hygroscopic-agent-containing enclosing layer 408 that is described with FIG. 11 to the structure of the organic electroluminescence element shown in FIG. 12, for example. This consideration reveals that use of a drying agent (e.g., calcium oxide, barium oxide, and silica gel which are introduced as preferable drying agents by document 1) is likely to cause a decrease in light extraction efficiency because such a drying agent has low transparency.

Further, in a case where the structure of the organic electroluminescence element shown in FIG. 12 is provided with the hygroscopic-agent-containing enclosing layer 408 that is described with FIG. 11, the area of the hygroscopic-agent-containing enclosing layer 408 is larger than that of the light-emitting layer 103. Hence, a non-light-emitting region between peripheries of the light-emitting layer 103 and the substrate 104 has a wide width.

Even when the drying agent with light transmissive is used in the organic electroluminescence element shown in FIG. 12, the light extraction efficiency is likely to be decreased due to scattering loss and absorption loss, for example. Additionally, in this case, there may be fewer options of material of the drying agent.

In view of the above insufficiency, the present invention has aimed to propose an organic electroluminescence element with reduced luminance unevenness and improved reliability.

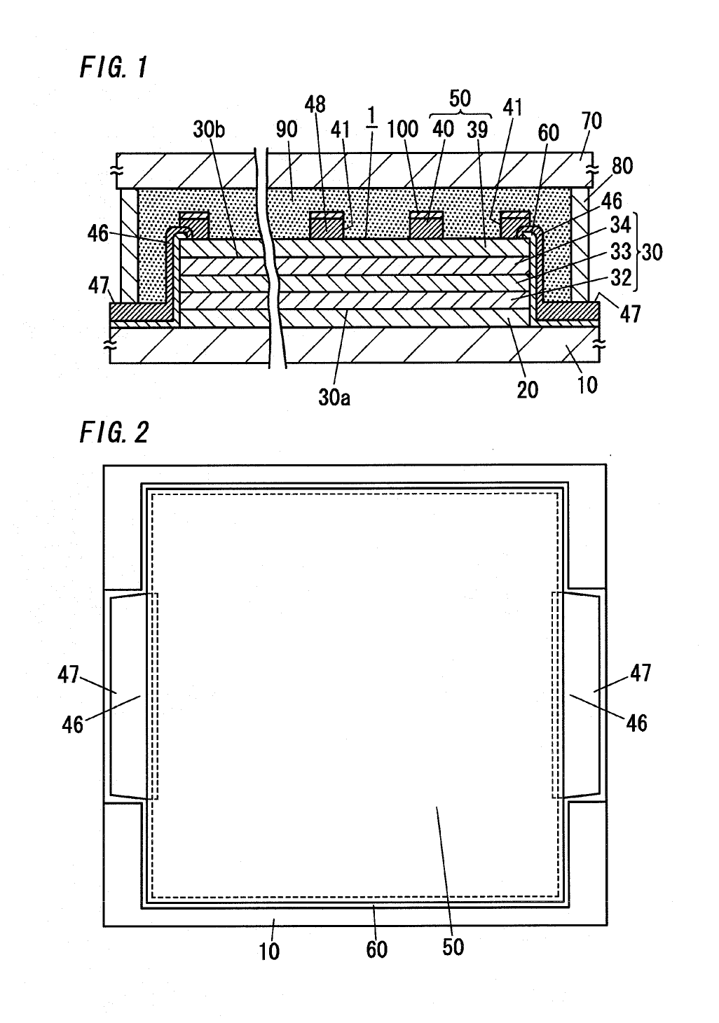

The following explanation referring to FIG. 1 to FIG. 10 is made to the organic electroluminescence element of one embodiment in accordance with the present invention.

As shown in FIG. 1, the organic electroluminescence element includes a substrate 10, a first electrode 20 on a surface (upper surface in FIG. 1) of the substrate 10, a second electrode 50 which is over the surface of the substrate 10 and faces the first electrode 20, and a functional layer 30 which is between the first electrode 20 and the second electrode 50 and includes a light-emitting layer 32.

In other words, the organic electroluminescence element includes: the functional layer 30 including the light-emitting layer 32; the first electrode (first electrode layer) 20; and the second electrode (second electrode layer) 50.

The functional layer 30 has a first surface (lower surface in FIG. 1) 30a and a second surface (upper surface in FIG. 1) 30b in a thickness direction. The first electrode 20 is positioned on the first surface 30a of the functional layer 30. The second electrode 50 is positioned on the second surface 30b of the functional layer 30.

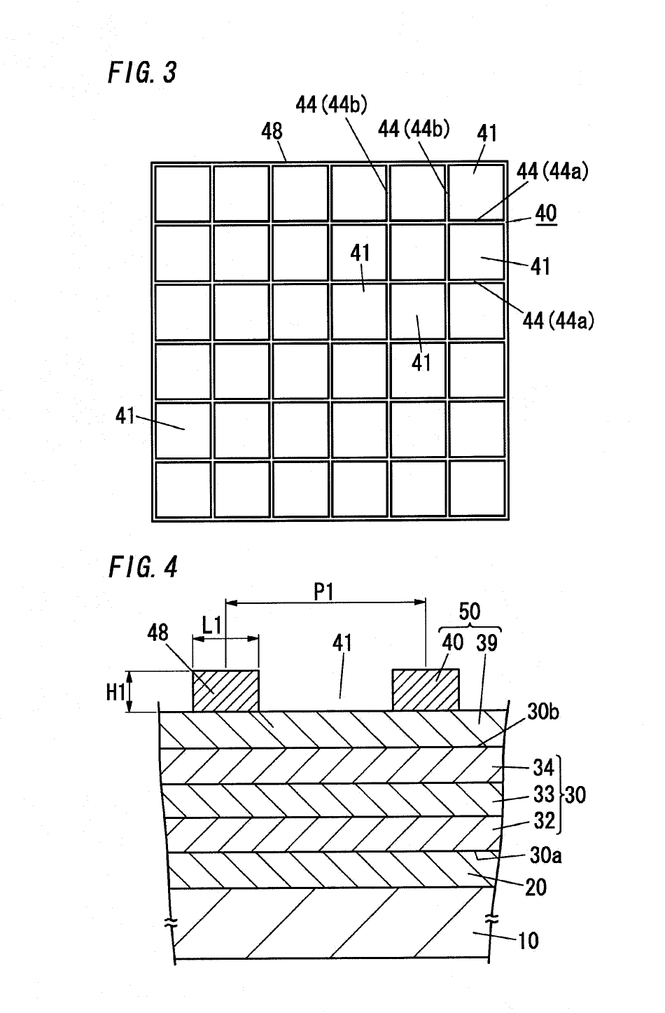

The second electrode 50 includes a patterned electrode 40. The patterned electrode 40 includes an opening part 41 (see FIG. 3 and FIG. 4) for allowing passage of light from the functional layer 30. In summary, in the organic electroluminescence element, the second electrode 50 includes the opening part 41 for passage of light emitted from the functional layer 30. In this regard, it is preferable that the second electrode 50 include a conductive polymer layer 39 being in contact with the functional layer 30 and that the patterned electrode 40 described above is on an opposite side of the conductive polymer layer 39 from the functional layer 30.

In other words, the second electrode 50 includes the patterned electrode 40, and the conductive polymer layer (electrically conductive layer) 39. The patterned electrode 40 includes an electrode part 48 covering the second surface 30b of the functional layer 30, and the opening part 41 formed in the electrode part 48 to expose the second surface 30b of the functional layer 30. The electrically conductive layer 39 is made of material allowing passage of light emitted from the light-emitting layer 32. The electrically conductive layer 39 is interposed between the second surface 30b of the functional layer 30 and the patterned electrode 40 so as to cover the second surface 30b of the functional layer 30. In the present embodiment, the patterned electrode 40 includes a plurality of opening parts 41.

In the organic electroluminescence element, each of the first electrode 20 and the patterned electrode 40 of the second electrode 50 has a resistivity (electrical resistivity) lower than a resistivity (electrical resistivity) of a transparent conducting oxide (TCO). Examples of the transparent conductive oxide include ITO, AZO, GZO, and IZO.

Further, the organic electroluminescence element includes a hygroscopic member 100 that is on an opposite side of the patterned electrode 40 from the functional layer 30. The hygroscopic member 100 is positioned on the electrode part 48 in such a way to expose the opening part 41. Besides, the hygroscopic member 100 is not necessarily positioned on the electrode part 48 so as to expose the entire opening part 41. In brief, the hygroscopic member 100 is allowed to partially overlap the opening part 41 unless the hygroscopic member 100 does not excessively prevent emission of light via the opening part 41. Additionally, the hygroscopic member 100 is not necessarily positioned on the electrode part 48 to wholly cover the electrode part 48 but may be positioned on the electrode part 48 to partially cover the electrode part 48. Note that, in the description to the embodiments of the present invention, the term “cover” means not only “cover something with being in direct contact with it” but also “cover something without being in direct contact with it with another layer being interposed”. In summary, the expression that the first layer “covers” the second layer means a situation where the second layer is positioned directly on the first layer or positioned on the first layer with the third layer being interposed between the first layer and the second layer.

Furthermore, the organic electroluminescence element includes an enclosing layer (cover substrate) 70 and a resin layer 90. The enclosing layer 70 is positioned over the surface of the substrate 10 to face the surface of the substrate 10. The enclosing layer 70 allows light to pass through. The resin layer 90 allows light to pass through and has a refractive index equal to a refractive index of the conductive polymer layer 39 or more. The resin layer 90 is interposed between the second electrode 50 and the enclosing layer (enclosing member) 70.

With this configuration, the organic electroluminescence element can emit light via the second electrode 50, the resin layer 90, and the enclosing layer 70. In brief, the organic electroluminescence element of the present embodiment can be used as a top emission type organic electroluminescence element.

In the organic electroluminescence element, the first electrode 20 can have a part (not shown) on which a layered film of the functional layer 30 and the second electrode 50 is not mounted and this part can be used as a first terminal. Alternatively, it is possible to provide a first terminal that is connected to the first electrode 20 via a first extension wire. Alternatively, the substrate 10 may be formed of a metal plate or a metal foil and an exposed part of the substrate 10 may be used as a first terminal.

The organic electroluminescence element includes a second terminal 47 electrically connected to the second electrode 50 via a second extension wire 46. The second extension wire 46 and the second terminal 47 are on the surface of the substrate 10. Alternatively, the second terminal 47 may be bent together with an insulating layer 60 described below and the substrate 10 towards an opposite side of the substrate 10 from the enclosing layer 70.

In the organic electroluminescence element, the insulating layer 60 mentioned above is formed continuously to extend over the surface of the substrate 10, a side surface of the first electrode 20, a side surface of the functional layer 30, and a periphery of the surface of the functional layer 30 close to the second electrode 50. Thus, in the organic electroluminescence element, the second extension wire 46 is electrically insulated from the functional layer 30 and the first electrode 20 by the insulating layer 60.

It is preferable that the organic electroluminescence element include a frame 80. The frame 80 is formed into a frame shape (rectangular frame shape in the present embodiment). The frame 80 is interposed between an entire periphery of the substrate 10 and an entire periphery of the enclosing layer 70. Additionally, the resin layer 90 is in a space enclosed by the substrate 10, the enclosing layer 70, and the frame 80 to cover an element member 1 that may be constituted by the first electrode 20, the functional layer 30, and the second electrode 50.

The following is a detailed explanation made to each component of the organic electroluminescence element.

The substrate 10 is formed into a rectangular shape in a plan view. Note that, the shape of the substrate 10 in a plan view is not limited to a rectangular shape, but may be a polygonal shape other than the rectangular shape, a circular shape or the like.

The substrate 10 is formed of a glass substrate, but is not limited thereto. For example, a plastic plate, a metal plate, or the like may be used for the substrate 10. Examples of materials of the glass substrate include soda-lime glass and non-alkali glass and the like. Examples of materials of the plastic plate include polyethylene terephthalate, polyethylene naphthalate, poly ether sulfone, polycarbonate and the like. Examples of materials of the metal plate include aluminum, copper, stainless steel and the like. As to the plastic plate, in order to suppress the transmission of water, it is preferred to use a plastic plate including a plastic substrate and a SiON film, SiN film or the like, formed on the plastic substrate. The substrate 10 may be rigid or flexible.

In a case where the substrate 10 is formed of a glass substrate, irregularity of the surface of the substrate 10 may cause a leak current of the organic electroluminescence element (i.e. may cause deterioration of the organic electroluminescence element). Therefore, in the case where the glass substrate is used for the substrate 10, it is preferred to prepare a glass substrate for device formation which is highly-polished such that the surface has a sufficiently small roughness.

With regard to a surface roughness of the surface of the substrate 10, an arithmetic average roughness Ra defined in JIS B 0601-2001 (ISO 4287-1997) is preferably 10 nm or less and is more preferably several nm or less. In contrast, when a plastic plate is used for the substrate 10, it is possible to obtain a substrate which has an arithmetical average roughness Ra of the surface that is several nm or less, at lowered cost, without performing highly precise polishing particularly.

In the organic electroluminescence element of the present embodiment, the first electrode 20 serves as a cathode and the second electrode 50 serves as an anode. In this case, a first carrier injected from the first electrode 20 to the functional layer 30 is an electron, and a second carrier injected from the second electrode 50 to the functional layer 30 is a hole.

The functional layer 30 includes the light-emitting layer 32, a second carrier transport layer 33, and a second carrier injection layer 34 that are arranged in this order from the first electrode 20. In this regard, the second carrier transport layer 33 and the second carrier injection layer 34 serve as a hole transport layer and a hole injection layer, respectively. Note that, in a case where the first electrode 20 serves as an anode and the second electrode 50 serves as a cathode, an electron transport layer and an electron injection layer can be used as the second carrier transport layer 33 and the second carrier injection layer 34, respectively, for example.

The structure of the aforementioned functional layer 30 is not limited to the example illustrated in FIG. 1. For example, a first carrier injection layer and a first carrier transport layer may be provided between the first electrode 20 and the light-emitting layer 32, and an interlayer may be interposed between the light-emitting layer 32 and the second carrier transport layer 33. In a case where the first electrode 20 serves as a cathode and the second electrode 50 serves as an anode, the first carrier injection layer serves as an electron injection layer and the first carrier transport layer serves as an electron transport layer.

Further, it is sufficient that the functional layer 30 includes at least the light-emitting layer 32 (i.e., the functional layer 30 may include only the light-emitting layer 32). Components other than the light-emitting layer 32, namely, the first carrier injection layer, the first carrier transport layer, the interlayer, the second carrier transport layer 33, the second carrier injection layer 34 and the like are optional. In brief, the functional layer 30 is only required to be designed to emit light in response to application of a predetermined voltage between the first electrode layer (first electrode) 20 and the second electrode layer (second electrode) 50.

The light-emitting layer 32 may be either a single-layer structure or a multilayer structure. In a case where white light is required, the light-emitting layer may be doped with three kinds of dye materials, i.e. red, green, blue dyes; may have a laminate structure including a blue light emitting layer with a hole transport property, a green light emitting layer with an electron transport property and a red light emitting layer with an electron transport property; or may have a laminate structure including a blue light emitting layer with an electron transport property, a green light emitting layer with an electron transport property and a red light emitting layer with an electron transport property.

Examples of materials of the light-emitting layer 32 include poly(p-phenylenevinylene) derivative, polythiophene derivative, poly(p-phenylene) derivative, polysilane derivative, and polyacetylene derivative; polymerized compound of such as polyfluorene derivative, polyvinyl carbazole derivative, chromoporic material, and luminescnce material of metal complexes; anthracene, naphthalene, pyrene, tetracene, coronene, perylene, phthaloperylene, naphthaloperylene, diphenylbutadiene, tetraphenylbutadiene, coumalin, oxadiazole, bisbenzoxazoline, bisstyryl, cyclopentadiene, coumalin, oxadiazol, bis benzo ide quinazoline, Bisusuchiriru, cyclopentadiene, quinoline-metal complex, tris(8-hydroxyquinolinate)aluminum complex, tris(4-methyl-8-quinolinate)aluminum complex, tris(5-phenyl-8-quinolinate)aluminum complex, aminoquinoline-metal complex, benzoquinoline-metal complex, tri-(p-terphenyl-4-yl)amine, pyrane, quinacridone, rubrene and their derivatives; 1-aryl-2,5-di(2-thienyl)pyrrole derivative, distyrylbenzene derivative, distyrylarylene derivative, styrylarylene derivative, styrylamine derivative, and various compounds containing a group (radical) that is formed of the above-listed luminescent material.

The material of the light-emitting layer 32 is not limited to compounds based on fluorescent dye listed above, and examples of materials of the light-emitting layer 32 include so-called phosphorescent material such as iridium complex, osmium complex, platinum complex, europium complex, and compounds or polymer molecules containing one of these complexes.

One or more materials listed above can be selected and used as necessary. The light-emitting layer 32 is preferably formed into a film shape with a wet process such as a coating method (e.g., a spin coating method, spray coating method, dye coating method, gravure printing method, and screen printing method). However, the light-emitting layer 32 may be formed into a film shape with a dry process such as a vacuum vapor deposition method and a transfer method as well as by the coating method.

Examples of material for the electron injection layer include metal fluorides (e.g., lithium fluoride and magnesium fluoride), metal halide compounds (e.g., metal chlorides typified by sodium chloride and magnesium chloride) and oxides such as titanium oxide, zinc oxide, magnesium oxide, calcium oxide, barium oxide and strontium oxide. In the case where these materials are used, the electron injection layer can be formed with a vacuum vapor deposition method.

Also, the electron injection layer can be made of an organic semiconductor material doped with dopant (such as alkali metal) for promoting electron injection. In the case where such material is used, the electron injection layer can be formed with a coating method.

Material of the electron transport layer can be selected from the group of compounds that allow electron transport. Examples of such types of compounds may include a metal complex that is known as electron transporting material (e.g., Alq3), and compounds having a heterocycle (e.g., phenanthroline derivatives, pyridine derivatives, tetrazine derivatives, and oxadiazole derivatives), but are not limited thereto, and any electron transport material that is generally known can be used.

The hole transport layer can be made of low-molecular material or polymeric material having a comparatively low LUMO (Lowest Unoccupied Molecular Orbital) level. Examples of material of the hole transport layer include polymer containing aromatic amine such as polyarylene derivative containing aromatic amine on the side chain or the main chain, e.g., polyvinyl carbazole (PVCz), polypyridine, polyaniline and the like. However, the material of the hole transport layer is not limited thereto. Note that, examples of material of the hole transport layer include 4,4′-bis[N-(naphthyl)-N-phenyl-amino]biphenyl (α-NPD), N,N′-bis(3-methylphenyl)-(1,1′-biphenyl)-4,4′-diamine (TPD), 2-TNATA, 4,4′,4″-tris(N-(3-methylphenyl)N-phenylamino)triphenylamine (MTDATA), 4,4′-N,N′-dicarbazolebiphenyl (CBP), Spiro-NPD, spiro-TPD, spiro-TAD, TNB and the like.

Examples of material of the hole injection layer include organic material containing thiophene, triphenylmethane, hydrazoline, amylamine, hydrazone, stilbene, triphenylamine and the like. In detail, examples of materials of the hole injection layer include aromatic amine derivative such as polyvinyl carbazole, polyethylenedioxythiophene:polystyrenesulfonate (PEDOT:PSS), TPD and the like. These materials can be used alone or in combination of two or more. The hole injection layer mentioned above can be formed into a film shape with a wet process such as a coating method (e.g., a spin coating method, spray coating method, dye coating method, and gravure printing method).

It is preferable that the interlayer has a carrier blocking function (in this configuration, an electron blocking function) of serving as a first carrier barrier (in this configuration, an electron barrier) which suppresses leakage of the first carrier (in this configuration, an electron) from the light-emitting layer 32 to the second electrode 50. Further, it is preferable that the interlayer has a function of transporting the second carrier (in this configuration, a hole) to the light-emitting layer 32, and a function of preventing quenching of an excited state of the light-emitting layer 32. Note that, in the present embodiment, the interlayer serves as an electron blocking layer which suppresses leakage of an electron from the light-emitting layer 32.

In the organic electroluminescence element, with providing the interlayer, it is possible to improve the luminous efficiency and prolong the lifetime. Examples of material of the interlayer include polyarylamine and derivative thereof, polyfluorene and derivative thereof, polyvinyl carbazole and derivative thereof, and triphenyldiamine derivative. The interlayer as mentioned above can be formed into a film shape with a wet process such as a coating method (e.g., a spin coating method, spray coating method, dye coating method, and gravure printing method).

The cathode is an electrode for injecting an electron (first carrier) treated as a first charge into the functional layer 30. In the case where the first electrode 20 serves as a cathode, the cathode is preferably made of an electrode material such as metal, alloy, or electrically conductive compound that has a small work function, and a mixture thereof. Further, it is preferable that the cathode is made of material having a work function of 1.9 eV or more to 5 eV or less in order to limit a difference between an energy level of the cathode and an LUMO (Lowest Unoccupied Molecular Orbital) level within an appropriate range.

Examples of electrode material of the cathode include aluminum, silver, magnesium, gold, copper, chrome, molybdenum, palladium, tin, and alloy of these and other metal such as magnesium-silver mixture, magnesium-indium mixture, aluminum-lithium alloy and the like.

The cathode may be formed of laminated film including a thin film made of aluminum and an ultrathin film (a thin film having a thickness of 1 nm or less so as to allow an electron to flow with tunneling injection) made of aluminum oxide, for example. Such an ultrathin film may be made of metal, metal oxide, or mixture of these and other metal.

In a case where the cathode is designed as a reflective electrode, it is preferable that the cathode be made of metal having high reflectance with respect to the light emitted from the light-emitting layer 32 and having a low resistivity, such as aluminum and silver.

Note that, in a case where the first electrode 20 is the anode that serves as the electrode for injecting a hole (second carrier) treated as the second charge into the functional layer 30, the first electrode 20 is preferably made of metal having a large work function. Further it is preferable that the anode is made of material having a work function of 4 eV or more to 6 eV or less in order to limit a difference between an energy level of the first electrode 20 and an HOMO (Highest Occupied Molecular Orbital) level within an appropriate range.

The conductive polymer layer 39 of the second electrode 50 may be made of a conductive polymer material such as polythiophene, polyaniline, polypyrrole, polyphenylene, polyphenylenevinylene, polyacetylene, and polycarbazole.

For the purpose of improving the conductivity, the conductive polymer material of the conductive polymer layer 39 may be doped with a dopant such as sulfonate acid, Lewis acid, proton acid, alkali metal, and alkali earth metal.

In this regard, it is preferable that the conductive polymer layer 39 have a lower resistivity. The electrical conductivity of the whole in a lateral direction (in-plane direction) thereof is improved with a decrease in the resistivity. Hence, it is possible to suppress an in-plane variation in a current flowing through the light-emitting layer 32, and therefore the luminance unevenness can be reduced.

The conductive polymer layer 39 can be formed into a film shape with a wet process such as a coating method (e.g., a spin coating method, spray coating method, dye coating method, gravure printing method, and screen printing method). However, the conductive polymer layer 39 may be formed into a film shape with a dry process such as a vacuum vapor deposition method and a transfer method as well as by the coating method.

The patterned electrode 40 of the second electrode 50 is an electrode made of material including metal powder and an organic binder. Examples of such kind of metal include silver, gold, and copper. Thus, in the organic electroluminescence element, the patterned electrode 40 of the second electrode 50 can have a resistivity and a sheet resistance that are lower than those of the second electrode 50 provided as a thin film made of the electrically conductive transparent oxide. Hence, the luminance unevenness can be reduced. Note that, the electrically conductive material of the patterned electrode 40 of the second electrode 50 may be selected from alloy and carbon black, as substitute for metal.

For example, the patterned electrode 40 can be formed by printing, with a screen printing method or a gravure printing method, paste (print ink) prepared by mixing metal powder with a set of an organic binder and an organic solvent.

Examples of materials of the organic binder include acrylic resin, polyethylene, polypropylene, polyethylene terephthalate, polymethylmethacrylate, polystyrene, polyether sulfone, polyarylate, polycarbonate resin, polyurethane, polyacrylonitrile, polyvinyl acetal, polyamide, polyimide, diacryl phthalate resin, cellulosic resin, polyvinyl chloride, polyvinylidene chloride, polyvinyl acetate, other thermoplastic resin, and copolymer containing at least different two of monomers constituting the above-listed resin. Note that, the material of the organic binder is not limited thereto.

The second extension wire 46 and the second terminal 47 are made of the same material as the patterned electrode 40 of the second electrode 50. However, each material of the second extension wire 46 and the second terminal 47 is not limited to particular one. In a case where the second extension wire 46 and the second terminal 47 are made of the same material as the patterned electrode 40 of the second electrode 50, the second extension wire 46, the second terminal 47, and the patterned electrode 40 can be formed simultaneously. The second terminal 47 is not limited to a single layer but may be a multiple layer constituted by two or more layers.

Note that in the organic electroluminescence element of the present embodiment, the thickness of the first electrode 20 is selected to be within a range of 80 nm to 200 nm, and the thickness of the light-emitting layer 32 is selected to be within a range of 60 nm to 200 nm, and the thickness of the second carrier transport layer 33 is selected to be within a range of 5 nm to 30 nm, and the thickness of the second carrier injection layer 34 is selected to be within a range of 10 nm to 60 nm, and the thickness of the conductive polymer layer 39 is selected to be within a range of 200 nm to 400 nm. However, the aforementioned values are only examples and the thicknesses thereof are not limited particularly.

The patterned electrode 40 is formed into a grid shape (a net-like shape) as shown in FIG. 1 and FIG. 3 and includes a plurality (6*6=36 in the instance shown in FIG. 3) of opening parts 41. In this regard, in the patterned electrode 40 shown in FIG. 3, each opening part 41 has a square shape when viewed in a plane. In brief, the patterned electrode 40 shown in FIG. 3 is formed into a square grid shape.

In the patterned electrode 40 shown in FIG. 3, the electrode part 48 includes a plurality of narrow line parts 44 (44a) extending in a first direction (left and right direction in FIG. 3), and a plurality of narrow line parts 44 (44b) extending in a second direction (upward and downward direction in FIG. 3) perpendicular to the first direction. The plurality of (seven, in the illustrated instance) narrow line parts 44a are arranged at regular intervals in the second direction. The plurality of (seven, in the illustrated instance) narrow line parts 44b are arranged at regular intervals in the first direction. The plurality of narrow line parts 44a and the plurality of narrow line parts 44b are perpendicular to each other. In the patterned electrode 40 shown in FIG. 3, a space enclosed by the adjacent narrow line parts 44a and 44a and the adjacent narrow line parts 44b and 44b defines the opening part 41.

In the second electrode 50, with regard to the dimensions of the patterned electrode 40 that has a square grid shape, for example, a line width L1 (see FIG. 4) is within a range of 1 μm to 100 μm, and a height H1 (see FIG. 4) is within a range of 50 nm to 100 μm, and a pitch P1 (see FIG. 4) is within a range of 100 μm to 2000 μm.

However, respective value ranges of the line width L1, the height H1 and the pitch P1 of the patterned electrode 40 of the second electrode 50 are not definite particularly, but may be selected appropriately based on the size in the plan view of the element member 1.

In this regard, to improve the use efficiency of the light produced in the light-emitting layer 32, it is preferable that the line width L1 of the patterned electrode 40 of the second electrode 50 is decreased. In contrast, to suppress the luminance unevenness by decreasing the resistance of the second electrode 50, it is preferable that the patterned electrode 40 have the broader line width L1. Hence, it is preferable that the line width L1 is appropriately selected depending on the planar size of the organic electroluminescence element, for example.

Further, it is preferable that the height H1 of the patterned electrode 40 of the second electrode 50 is within a range of 100 nm to 10 μm. This range may be selected in view of: decreasing the resistance of the second electrode 50; improving the efficient use of the material (material use efficiency) of the patterned electrode 40 in a process of forming the patterned electrode 40 with a coating method such as a screen printing method; and selecting an appropriate radiation angle of the light emitted from the functional layer 30.

Furthermore, in the organic electroluminescence element of the present embodiment, each opening part 41 in the patterned electrode 40 may be formed into such an opening shape that an opening area is gradually increased with an increase in a distance from the functional layer 30.

Thus, in the organic electroluminescence element, a spread angle of the light emitted from the functional layer 30 can be increased and therefore the luminance unevenness can be more reduced. Furthermore, in the organic electroluminescence element, it is possible to reduce a reflection loss and an absorption loss at the patterned electrode 40 of the second electrode 50. Therefore, the external quantum efficiency of the organic electroluminescence element can be more improved.

In a case where the patterned electrode 40 is formed into a grid shape, the shape of each opening part 41 is not limited to a square shape, but may be a rectangular shape, an equilateral triangle shape, or a regular hexagonal shape, for example.

In a case where the plan shape of each opening part 41 is an equilateral triangle shape, the patterned electrode 40 is formed into a triangle grid shape. In a case where the shape of each opening part 41 is a regular hexagonal shape, the patterned electrode 40 is formed into a hexagonal grid shape. Note that the shape of the patterned electrode 40 is not limited to a grid shape, but may be a comb shape, for example. The patterned electrode 40 may also be constituted by a set of two patterned electrodes each formed into a comb shape. In brief, the organic electroluminescence element may include a plurality of patterned electrodes 40.

Further, the number of opening parts 41 of the patterned electrode 40 is not particularly limited, but may be one or more. For example, in the case where the patterned electrode 40 has a comb shape or the patterned electrode 40 is constituted by the two patterned electrodes each having a comb shape, the number of opening part 41 can be one.

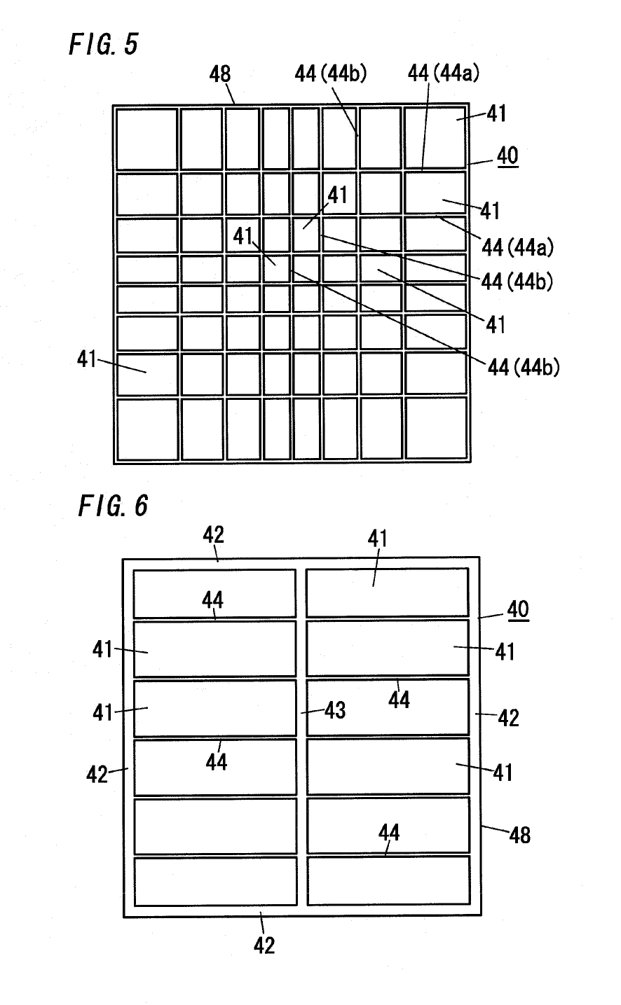

Further, the patterned electrode 40 may be formed to have a planar shape shown in FIG. 5, for example. That is, the patterned electrode 40 may be formed into such a shape in a plan view that the straight narrow line parts 44 of the patterned electrode 48 a have the same line width and the opening area of the opening part 41 is decreased by decreasing the interval between the adjacent narrow line parts 44 with an increase in a distance from the periphery of the patterned electrode 40.

In the patterned electrode 40 shown in FIG. 5, a plurality (nine, in the illustrated instance) of narrow line parts 44a are arranged in a second direction (upward and downward direction in FIG. 5) such that an interval between the narrow line parts 44a becomes shorter towards the center than at the edge of the electrode part 48. A plurality (nine, in the illustrated instance) of narrow line parts 44b are arranged in a first direction (left and right direction in FIG. 5) such that an interval between the narrow line parts 44b becomes shorter towards the center than at the edge of the electrode part 48.

In the organic electroluminescence element, the patterned electrode 40 of the second electrode 50 is formed into the planar shape shown in FIG. 5 and, therefore, in contrast to the case where the patterned electrode 40 is formed into the planar shape shown in FIG. 3, it is possible to improve the luminous efficiency of the second electrode 50 at the center which is farther from the second terminal 47 (see FIG. 1) than the periphery is. Consequently, the external quantum efficiency of the organic electroluminescence element can be improved.

Further, in the organic electroluminescence element, since the patterned electrode 40 of the second electrode 50 is formed into the planar shape shown in FIG. 5, in contrast to a case where the patterned electrode 40 is formed into the planer shape shown in FIG. 3, it is possible to suppress current crowding at a periphery of the functional layer 30 which is close to the second terminal 47. Consequently, the lifetime of the organic electroluminescence element can be extended.

Further, the patterned electrode 40 of the second electrode 50 may be formed to have a planar shape shown in FIG. 6, for example. In other words, the patterned electrode 40 is formed such that in a plan view widths of four first narrow line parts 42 defining the periphery of the patterned electrode 40 and a width of a single second narrow line part 43 located at the center in a left and right direction of FIG. 6 are greater than a width of a narrow line part (third narrow line part) 44 located between the first narrow line part 42 and the second narrow line part 43.

In the organic electroluminescence element, since the patterned electrode 40 of the second electrode 50 is formed into the planar shape shown in FIG. 6, in contrast to a case where the patterned electrode 50 is formed into the planar shape shown in FIG. 3, it is possible to improve the luminous efficiency of the second electrode 50 at the center which is farther from the second terminal 47 (see FIG. 1) than the periphery is. Consequently, the external quantum efficiency of the organic electroluminescence element can be improved.

Note that, in the case where the patterned electrode 40 is formed into the planar shape shown in FIG. 6, with increasing the heights of the first narrow line part 42 and the second narrow line part 43 that have the relatively large widths to be greater than the height of the third narrow line part 44, it is possible to more decrease the resistances of the first narrow line part 42 and the second narrow line part 43.

The insulating layer 60 may be made of a photo-curable resin such as epoxy resin, acrylic resin, and silicone resin.

The insulating layer 60 is formed into a rectangular frame shape in a plan view. The insulating layer 60 has a part interposed between the substrate 10 and the second extension wire 46 as well as the second terminal 47. Note that, the plan view of the insulating layer 60 is not limited to particular one.

The enclosing layer 70 serving as the cover substrate is formed of a glass substrate, but is not limited thereto. For example, a plastic plate or the like may be used for the second substrate 70. Examples of materials of the glass substrate include soda-lime glass, non-alkali glass and the like. Examples of material of the plastic plate include polyethylene terephthalate, polyethylene naphthalate, poly ether sulfone, polycarbonate and the like. Note that, in a case where the substrate 10 is formed of a glass substrate, the enclosing layer 70 is preferably formed of the same material of the substrate 10, that is, a glass substrate.

In the present embodiment, the enclosing layer 70 has a flat plate shape, but the shape of the enclosing layer 70 is not limited particularly. For example, the enclosing layer 70 may be provided with a recessed portion for accommodating the element member 1 at a surface thereof facing the substrate 10, and the entire area surrounding the recessed portion within the facing surface may be bonded to the substrate 10.

This configuration has an advantage that there is no need to prepare the frame 80 provided as a separate part from the enclosing layer 70. In contrast, in a case where the enclosing layer 70 formed into a flat plate shape and the frame 80 formed into a frame shape are provided as separate parts, there is an advantage that it is possible to use materials satisfying the respective requirements of an optical property (e.g., an optical transmittance and a refractive index) necessary for the enclosing layer 70 and a property (e.g., a gas barrier property) necessary for the frame 80.

The frame 80 and the first surface of the substrate 10 are bonded to each other by means of a first bonding material. The first bonding material is epoxy resin, but is not limited thereto. For example, acrylic resin or the like can be used as the first bonding material. Epoxy resin, acrylic resin etc. used as the first bonding material may be ultraviolet-curing resin, thermosetting resin, or the like. Also, epoxy resin containing filler (made of e.g. silica, alumina) also can be used for the first bonding material. The frame 80 is bonded in an airtight manner to the surface of the substrate 10 at the entire periphery of the surface of the frame 80 facing the substrate 10.

The frame 80 and the enclosing layer 70 are bonded to each other by means of a second bonding material. The second bonding material is epoxy resin, but is not limited thereto. For example, acrylic resin, fritted glass or the like can be used as the second bonding material. Epoxy resin, acrylic resin etc. used as the second bonding material may be ultraviolet-curing resin, thermosetting resin, or the like. Also, epoxy resin containing filler (made of e.g. silica, alumina) also can be used for the second bonding material. The frame 80 is bonded in an airtight manner to the enclosing layer 70 at the entire periphery of the surface of the frame 80 facing the enclosing layer 70.

In the organic electroluminescence element of the present embodiment, a light transmissive resin used as material of the resin layer 90 have a refractive index not smaller than a refractive index of material of the conductive polymer layer 39 of the second electrode 50. Such a light transmissive resin may be an imide resin modified to have a higher refractive index, for example.

The hygroscopic member 100 may be made of a photo-curable resin (e.g., an epoxy resin, an acrylic resin, and a silicone resin) containing a hygroscopic agent.

It is preferable that the hygroscopic agent be selected from alkaline-earth metal oxide and sulfate. The alkaline-earth metal oxide may include calcium oxide, barium oxide, magnesium oxide, and strontium oxide, for example. The sulfate may include lithium sulfate, sodium sulfate, gallium sulfate, titanium sulfate, nickel sulfate, for example. Further, the hygroscopic agent may be selected from calcium chloride, magnesium chloride, copper chloride, and magnesium oxide. Additionally the hygroscopic agent may be a hygroscopic organic compound such as silica gel and polyvinyl alcohol. The hygroscopic agent is not limited to materials listed above. However, in these materials, calcium oxide, barium oxide, and silica gel are preferable. Note that, content by percentage of the hygroscopic agent in the hygroscopic member 100 is not limited particularly.

The hygroscopic member 100 has substantially the same plan shape as the patterned electrode 40. However, it is sufficient that the hygroscopic member 100 is on the patterned electrode 40 in such a way to expose the opening part 41 of the patterned electrode 40. In summary, the hygroscopic member 100 does not necessarily have substantially the same plan shape as the patterned electrode 40.

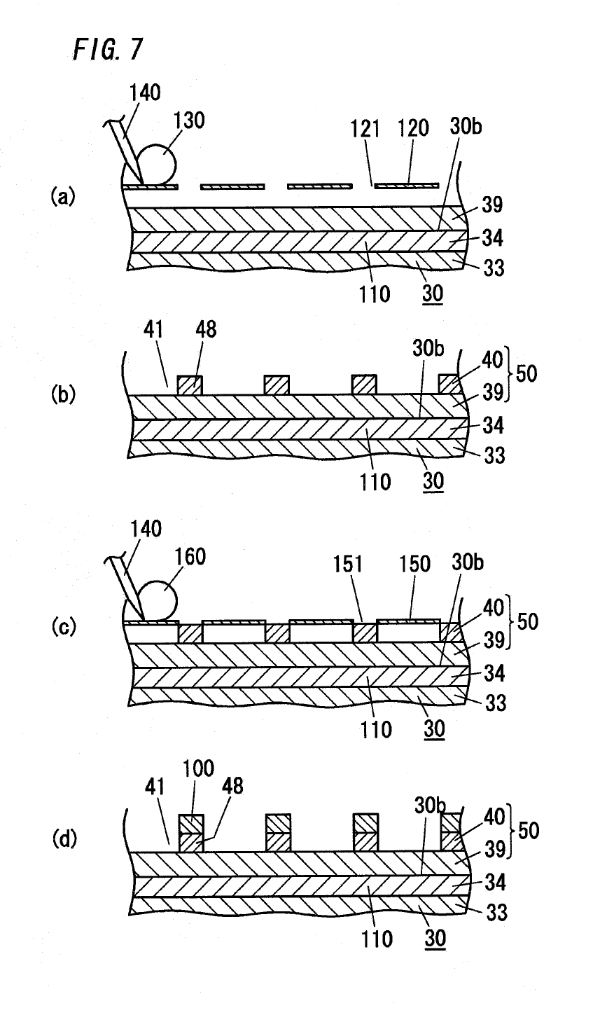

For example, a method of forming the patterned electrode 40 and the hygroscopic member 100 can be implemented by use of screen printing, as shown in (a) to (d) of FIG. 7.

First, as shown in (a) of FIG. 7, a substrate 110 constituted by the functional layer 30 and the electrically conductive layer 39 formed on the second surface 30b of the functional layer 30 is prepared. A screen 120 for forming the patterned electrode 40 is positioned above the substrate 110 (above the second surface 30b of the functional layer 30). The screen 120 is provided with openings 121 shaped depending on the shape of the electrode part 48 of the patterned electrode 40.

Next, print ink 130 as material of the patterned electrode 40 is applied onto the screen 120. Note that, the print ink 130 may be a paste produced by mixing metal powder with an organic binder and an organic solvent, for example.

Thereafter, the print ink 130 is transferred onto a surface (upper surface in (a) of FIG. 7) of the electrically conductive layer 39 with a squeegee 140. Subsequently, the print ink 130 is cured or dried. By doing this, the patterned electrode 40 is formed on the surface of the electrically conductive layer 39, as shown in (b) of FIG. 7.

After that, as shown in (c) of FIG. 7, a screen 150 for forming the hygroscopic member 100 is positioned above the patterned electrode 40. The screen 150 is provided with openings 151 shaped depending on the shape of the hygroscopic member 100.

Subsequently, print ink 160 as material of the hygroscopic member 100 is applied onto the screen 150. Note that, the print ink 160 may be a photo-curable resin (such as epoxy resin, acrylic resin, and silicone resin) containing a hygroscopic agent.

Next, the print ink 160 is transferred onto the patterned electrode 40 (the electrode part 48) with the squeegee 140. Subsequently, the print ink 160 is cured or dried. By doing this, the hygroscopic member 100 is formed on the electrode part 48 of the patterned electrode 40, as shown in (d) of FIG. 7.

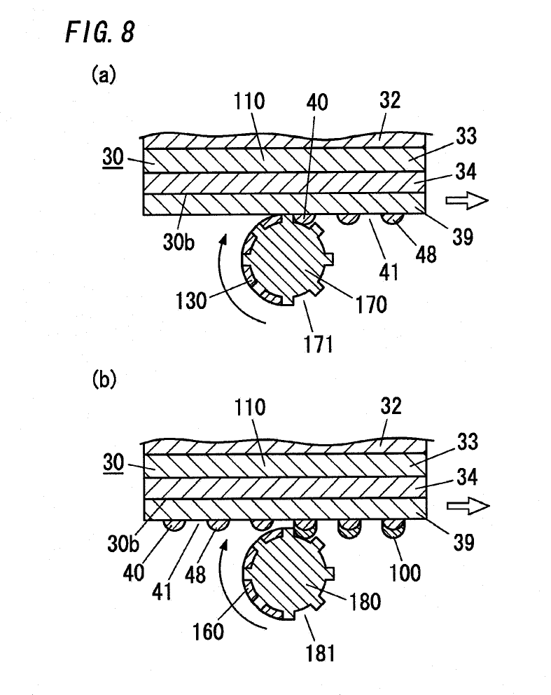

An alternative method of forming the patterned electrode 40 and the hygroscopic member 100 can be implemented by use of gravure printing, as shown in (a) and (b) of FIG. 8.

In the method using the gravure printing, the substrate 110 constituted by the functional layer 30 and the electrically conductive layer 39 formed on the second surface 30b of the functional layer 30 is prepared. Additionally, a cylinder (plate cylinder) 170 for forming the patterned electrode 40 and a cylinder 180 for forming the hygroscopic member 100 are prepared.

The cylinder 170 is provided with cells (recesses) 171 for forming the patterned electrode 40 having a desired shape. The print ink 130 is supplied into the cells 171 of the cylinder 170 from an ink reservoir (not shown).

The cylinder 180 is provided with cells (recesses) 181 for forming the hygroscopic member 100 having a desired shape. The print ink 160 is supplied into the cells 181 of the cylinder 180 from an ink reservoir (not shown).

In the method using the gravure printing, the cylinder 170 is pressed against the surface (lower surface in (a) of FIG. 8) of the electrically conductive layer 39 of the substrate 110 with rotating, while the substrate 110 is moved in a predetermined direction (direction designated by the arrow in (a) of FIG. 8). Consequently, the print ink 130 in the cells 171 of the cylinder 170 is transferred onto the surface of the substrate 110 (the surface of the electrically conductive layer 39). Subsequently, the print ink 130 is cured or dried. By doing this, the patterned electrode 40 is formed on the surface of the electrically conductive layer 39 (see (a) of FIG. 8).

Next, the cylinder 180 is pressed against the surface (lower surface in (b) of FIG. 8) of the substrate 110 with rotating, while the substrate 110 is moved in a predetermined direction (direction designated by the arrow in (b) of FIG. 8). Consequently, the print ink 160 in the cells 181 of the cylinder 180 is transferred onto the surface of the substrate 110 (the surface of the electrode part 48). Subsequently, the print ink 160 is cured or dried. By doing this, the hygroscopic member 100 is formed on the surface of the electrode part 48 of the patterned electrode 40 (see (b) of FIG. 8).

The organic electroluminescence element of the present embodiment described above includes: the substrate 10; the first electrode 20 on the surface of the substrate 10; the second electrode 50 which is over the surface of the substrate 10 and faces the first electrode 20; and the functional layer 30 which is between the first electrode 20 and the second electrode 50 and includes at least the light-emitting layer 32. Further, in the organic electroluminescence element, the second electrode 50 includes the patterned electrode 40 that includes the opening part 41 (see FIG. 3 and FIG. 4) for allowing passage of light from the functional layer 30, and the hygroscopic member 100 is on the opposite side of the patterned electrode 40 from the functional layer 30. In this regard, the hygroscopic member 100 is on the patterned electrode 40 in such a way to expose the opening part 41 of the patterned electrode 40.

In other words, the organic electroluminescence element of the present embodiment includes: the functional layer 30 including the light-emitting layer 32 and having the first surface 30a and the second surface 30b in the thickness direction; the first electrode layer 20 positioned on the first surface 30a of the functional layer 30; the second electrode layer 50 positioned on the second surface 30b of the functional layer 30; and the hygroscopic member 100 absorbing moisture. The second electrode layer 50 includes the patterned electrode 40. The patterned electrode 40 includes: the electrode part 48 covering the second surface 30b of the functional layer 30; and the opening part 41 formed in the electrode part 48 to expose the second surface 30b of the functional layer 30. The hygroscopic member 100 is positioned on the electrode part 48 to expose the opening part 41.

Accordingly, the organic electroluminescence element of the present embodiment can have the reduced luminance unevenness and the improved reliability. Further, it is possible to decrease a width of a non-light-emitting region between peripheries of the light-emitting layer 32 and the substrate 10. Note that, in the organic electroluminescence element, a laminated structure which is an overlap of the functional layer 30, the first electrode 20 and the second electrode 50 defines a light-emitting region.

Further, in the organic electroluminescence element of the present embodiment, the electrode part 48 is covered with the hygroscopic member 100. The hygroscopic member 100 has a reflectance (especially, for light emitted from the functional layer 30) lower than that of the electrode part 48. Hence, reflection of light by the electrode part 48 can be reduced. Consequently, it is possible to suppress glare caused by the electrode part 48.

Additionally, in the organic electroluminescence element of the present embodiment, as described above, the second electrode 50 includes the conductive polymer layer 39 and the aforementioned patterned electrode 40. The conductive polymer layer 39 is in contact with the functional layer 30. The patterned electrode 40 is on the opposite side of the conductive polymer layer 39 from the functional layer 30.

In other words, in the organic electroluminescence element of the present embodiment, the second electrode 50 includes the electrically conductive layer 39 made of material allowing passage of light emitted from the light-emitting layer 32. The electrically conductive layer 39 is interposed between the second surface 30b of the functional layer 30 and the patterned electrode 40 so as to cover the second surface 30b of the functional layer 30.

According to the organic electroluminescence element, in contrast to a structure devoid of the conductive polymer layer (electrically conductive layer) 39, it is possible to improve the property of injecting carriers from the second electrode (second electrode layer) 50 into the functional layer 30. Therefore, the external quantum efficiency can be improved. Note that, this configuration is optional.

With regard to the organic electroluminescence element illustrated in FIG. 12 described above, a medium in a space between the electrode 102 and the enclosing member 107 is not clearly disclosed. In the organic electroluminescence element illustrated in FIG. 12, when the space is filled with an inert gas, the medium in the space between the electrode 102 and the enclosing member 107 has a refractive index lower than refractive indices of the light-emitting layer 103, the hole injection and transport layer 106, and the electrode 102. Hence, reflection loss caused by total reflection at an interface between the electrode 102 and the medium is likely to occur.

In contrast, the organic electroluminescence element of the present embodiment further includes the enclosing layer 70 and the resin layer 90. The enclosing layer 70 is light transmissive and is positioned over the surface of the substrate 10 to face the surface of the substrate 10. The resin layer 90 is light transmissive and has a refractive index not less than a refractive index of the conductive polymer layer 39. The resin layer 90 is interposed between the second electrode 50 and the enclosing layer 70.

In other words, the organic electroluminescence element of the present embodiment further includes the substrate 10 and the enclosing member (enclosing layer) 70. The first electrode layer 20 is formed on the substrate 10. The enclosing member 70 is made of material allowing passage of light emitted from the light-emitting layer 32. The enclosing member 70 is fixed to the substrate 10 to form a space between the enclosing member 70 and the substrate 10 for accommodating the functional layer 30, the first electrode layer 20, and the second electrode layer 50.

Hence, the organic electroluminescence element of the present embodiment allows extraction of light via the second electrode layer 50 and the enclosing member 70. In brief, the organic electroluminescence element of the present embodiment can be used as a top emission type organic electroluminescence element. Note that, this configuration is optional.

Further, the organic electroluminescence element of the present embodiment includes the resin layer 90 allowing passage of light emitted from the light-emitting layer 32. The resin layer 90 is interposed between the second electrode layer 50 and the enclosing member 70. The resin layer 90 has a refractive index equal to a refractive index of the electrically conductive layer 39 or more.

Hence, the organic electroluminescence element of the present embodiment can have an improved light extraction efficiency. Note that, this configuration is optional.

Especially, the resin layer 90 is formed by filling a space between the second electrode layer 50 and the enclosing member 70 with a light transmissive material allowing passage of light emitted from the light-emitting layer 32.

Moreover, in the organic electroluminescence element of the present embodiment, the first electrode layer 20 is designed to reflect light emitted from the light-emitting layer 32.

Consequently, it is possible to improve the light extraction efficiency. Note that, these configurations are optional.

In this organic electroluminescence element, it is preferable that the second electrode 50 serves as an anode and that the functional layer 30 includes the hole injection layer 34 on the side of the light-emitting layer 32 close to the second electrode 50. Thus, in the organic electroluminescence element, it is possible to more efficiently inject holes of the second carriers into the light-emitting layer 32 and consequently improve the external quantum efficiency.

It is preferred that the organic electroluminescence element includes a light extraction structure (not shown) on the outer surface of the enclosing layer 70 (the opposite side of the enclosing layer 70 from the substrate 10) for suppressing reflection of light emitted from the light-emitting layer 32 at the outer surface.

For example, the above light extraction structure may be an uneven structure having a two-dimensional periodic structure. In a case where the wavelength of the light emitted from the light-emitting layer falls within a range of 300 nm to 800 nm, the periodic length of such a two-dimensional periodic structure is preferably within a range of quarter to tenfold of a wavelength λ. The wavelength λ denotes the wavelength of the light in the medium (i.e. λ is obtained by dividing the wavelength in vacuum by the refractive index of the medium).

Such an uneven structure can be preliminarily formed on the outer surface with an imprint method such as a thermal imprint method (a thermal nanoimprint method) and a photo imprint method (a photo nanoimprint method). Depending on material of the enclosing layer 70, the enclosing layer 70 can be formed with injection molding. In this case, the uneven structure can be formed directly on the enclosing layer 70 by using a proper mold in a process of injection molding. Also, the uneven structure can be formed of a member separate from the enclosing layer 70. For example, the uneven structure can be constituted by a prismatic sheet (e.g. a light diffusion film such as LIGHT-UP GM3 (“LIGHT UP” is a registered trademark) available from KIMOTO CO., LTD.).

The organic electroluminescence element of the present embodiment includes the light extraction structure and therefore it is possible to reduce the reflection loss of the light which is emitted from the light-emitting layer 32 and then strikes the outer surface of the enclosing layer 70. As a result, this configuration can improve the light extraction efficiency.

### (First Modification)

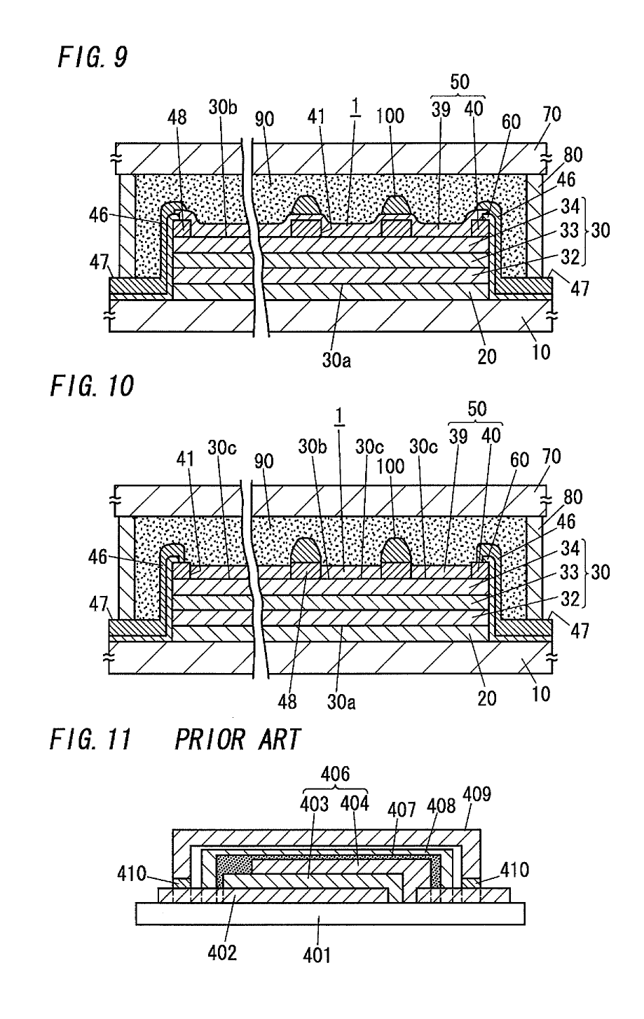

FIG. 9 shows the first modification of the organic electroluminescence element of the present embodiment. In this first modification, like the basic example illustrated in FIG. 1, the second electrode layer 50 further includes the electrically conductive layer 39 made of material allowing passage of light emitted from the light-emitting layer 32. However, in the first modification, the electrically conductive layer 39 is interposed between the patterned electrode 40 and the hygroscopic member 100 so as to cover the second surface 30b of the functional layer 30.

The electrically conductive layer 39 is formed to cover entirely both the second surface 30b of the functional layer 30 and the patterned electrode 40, for example.

For example, the second electrode layer 50 and the hygroscopic member 100 of the first modification are formed as follows. First, the patterned electrode 40 is formed on the second surface 30b of the functional layer 30 with the screen printing or the gravure printing. Subsequently, the electrically conductive layer 39 is formed with the coating method, the vacuum vapor deposition method, the transfer method, or the like. At last, the hygroscopic member 100 is formed on a part of the electrically conductive layer 39 covering the electrode part 48 with the screen printing or the gravure printing.

According to the first modification, in contrast to a structure devoid of the conductive polymer layer (electrically conductive layer) 39, the organic electroluminescence element can have the improved property of injecting carriers from the second electrode (second electrode layer) 50 into the functional layer 30. Therefore, the external quantum efficiency can be improved.

### (Second Modification)

FIG. 10 shows the second modification of the organic electroluminescence element of the present embodiment. In this second modification, like the basic example illustrated in FIG. 1, the second electrode layer 50 further includes the electrically conductive layer 39 made of material allowing passage of light emitted from the light-emitting layer 32. However, in the second modification, the electrically conductive layer 39 is positioned inside the opening part 41 so as to cover a region 30c of the second surface 30b of the functional layer 30 exposed through the opening part 41 and be in contact with the electrode part 48.

For example, the second electrode layer 50 and the hygroscopic member 100 of the second modification are formed as follows. First, the patterned electrode 40 is formed on the second surface 30b of the functional layer 30 with the screen printing or the gravure printing. Subsequently, the electrically conductive layer 39 is formed inside the opening part 41 of the patterned electrode 40 with the screen printing or the gravure printing. At last, the hygroscopic member 100 is formed on the electrode part 48 of the patterned electrode 40 with the screen printing or the gravure printing.

According to the second modification, in contrast to a structure devoid of the conductive polymer layer (electrically conductive layer) 39, the organic electroluminescence element can have the improved property of injecting carriers from the second electrode (second electrode layer) 50 into the functional layer 30. Therefore, the external quantum efficiency can be improved. Note that, this configuration is optional.

Note that, in a case where the patterned electrode 40 includes a plurality of opening parts 41, the electrically conductive layer 39 may be positioned inside each of the plurality of opening parts 41 or be positioned inside each specific opening part 41 of the plurality of opening parts 41. Further, the electrically conductive layer 39 need not necessarily cover the whole of the region 30c exposed via the opening part 41. In brief, it is sufficient that the electrically conductive layer 39 partially covers the region 30c.

The organic electroluminescence elements described in the above embodiments are preferably available, for example, for organic electroluminescence elements for lighting use. However, the organic electroluminescence elements are available for not only lighting use but also other use.

Note that, the figures used for describing the respective embodiments are schematic ones, and do not necessarily show the actual ratio of the length, thickness, or the like of the components.

1. An organic electroluminescence element comprising:
a functional layer including a light-emitting layer and having a first surface and a second surface in a thickness direction;
a first electrode layer positioned on the first surface of the functional layer;
a second electrode layer positioned on the second surface of the functional layer; and
a hygroscopic member absorbing moisture,
wherein:
the second electrode layer includes a patterned electrode;
the patterned electrode includes
an electrode part covering the second surface of the functional layer, and
an opening part formed in the electrode part to expose the second surface of the functional layer; and
the hygroscopic member is positioned on the electrode part to expose the opening part.

2. The organic electroluminescence element as set forth in claim 1,
wherein:
the second electrode layer further includes an electrically conductive layer made of material allowing passage of light emitted from the light-emitting layer; and
the electrically conductive layer is interposed between the second surface of the functional layer and the patterned electrode so as to cover the second surface of the functional layer.

3. The organic electroluminescence element as set forth in claim 1,
wherein:
the second electrode layer further includes an electrically conductive layer made of material allowing passage of light emitted from the light-emitting layer; and
the electrically conductive layer is interposed between the patterned electrode and the hygroscopic member so as to cover the second surface of the functional layer.

4. The organic electroluminescence element as set forth in claim 1,
wherein:
the second electrode layer further includes an electrically conductive layer made of material allowing passage of light emitted from the light-emitting layer; and
the electrically conductive layer is positioned inside the opening part so as to cover a region of the second surface of the functional layer exposed through the opening part and be in contact with the electrode part.

5. The organic electroluminescence element as set forth in claim 2, further comprising:
a substrate; and
an enclosing member,
wherein:
the first electrode layer is formed on the substrate;
the enclosing member is made of material allowing passage of light emitted from the light-emitting layer; and
the enclosing member is fixed to the substrate to form a space between the enclosing member and the substrate for accommodating the functional layer, the first electrode layer, and the second electrode layer.

6. The organic electroluminescence element as set forth in claim 5, further comprising a resin layer allowing passage of light emitted from the light-emitting layer,
wherein:
the resin layer is interposed between the second electrode layer and the enclosing member; and
the resin layer has a refractive index not less than a refractive index of the electrically conductive layer.

7. The organic electroluminescence element as set forth in claim 6,
wherein
the resin layer is formed by filling a space between the second electrode layer and the enclosing member with a light transmissive material allowing passage of light emitted from the light-emitting layer.

8. The organic electroluminescence element as set forth in claim 5, wherein
the first electrode layer is designed to reflect light emitted from the light-emitting layer.
